(19) United States
(12) Patent Application Publication
(10) Pub. No.: US 2011/0039389 A1
(43) Pub. Date: Feb. 17, 2011

(54) MANUFACTURING METHOD OF SEMICONDUCTOR DEVICE

(75) Inventors: Koji YAMASHITA, Billerica, MA (US); Yasushi AKASAKA, Hsinchu (TW)

Correspondence Address: CANTOR COLBURN LLP, 20 Church Street, 22nd Floor, Hartford, CT, 06103, US

(73) Assignee: TOKYO ELECTRON LIMITED, Tokyo (JP)

(21) Appl. No.: 12/851,605

(22) Filed: Aug. 6, 2010

(30) Foreign Application Priority Data
Aug. 11, 2009 (JP) 2009-186526

(51) Int. Cl. H01L 21/336; H01L 21/18

(52) U.S. Cl. 438/303; 438/595; 438/703; 438/696; 257/E21.085; 257/E21.409

(57) ABSTRACT

Provided is a manufacturing method of a semiconductor device, the manufacturing method including forming a first thin film on a substrate; forming a second thin film, which is different from the first thin film, on the first thin film; forming a sacrificial film, which is a film different from the second thin film, on the second thin film; forming a sacrificial film pattern by processing the sacrificial film into a pattern having desired intervals through etching; coating a silicon oxide film on the sacrificial film pattern by intermittently supplying a silicon-containing precursor and an oxygen-containing gas onto the substrate; forming sidewall spacers on the sidewalls of the sacrificial film by etching the silicon oxide film; removing the sacrificial film; and processing the first film and the second film by using the sidewall spacers as a mask.

### CROSS-REFERENCE TO RELATED PATENT APPLICATIONS

This application claims the benefit of Japanese Patent Application No. 2009-186526, filed on Aug. 11, 2009, in the Japan Patent Office, the disclosure of which is incorporated herein in its entirety by reference.

### BACKGROUND OF THE INVENTION

1. Field of the Invention

The present invention relates to a manufacturing method of a semiconductor device, and more particularly, to formation of a thin film, such as a sidewall film or the like, which is formed on a metal member or a high-permittivity (high-k) member.

2. Description of the Related Art

After a gate electrode is formed, if a sidewall spacer is formed by using CVD method, a metal member and a high-k member react due to a film formation temperature or plasma, and thus an oxide film is formed or the metal member and the high-k member are spoiled. As a result, characteristics of the metal member and the high-k member are deteriorated.

[Patent Document 1] Japanese Patent Laid-Open Publication No. 2005-56997

### SUMMARY OF THE INVENTION

The present invention provides a manufacturing method of a semiconductor device, by which deterioration of the film quality of a metal film or a high-k film can be suppressed.

According to an aspect of the present invention, there is provided a manufacturing method of a semiconductor device, the manufacturing method including forming a first thin film on a substrate; forming a second thin film, which is different from the first thin film, on the first thin film; forming a sacrificial film formed of a film different from the second thin film, on the second thin film; forming a sacrificial film pattern by processing the sacrificial film into a pattern having desired intervals through etching; coating a silicon oxide film on the sacrificial film pattern by intermittently supplying a silicon-containing precursor and an oxygen-containing gas onto the substrate; forming sidewall spacers on the sidewalls of the sacrificial film by etching the silicon oxide film; removing the sacrificial film; and processing the first film and the second film by using the sidewall spacers as a mask.

According to another aspect of the present invention, there is provided a manufacturing method of a semiconductor device, the manufacturing method including forming a first thin film on a substrate; forming a second thin film, which is different from the first thin film, on the first thin film; forming a sacrificial film, which is a film different from the second thin film, on the second thin film; forming a sacrificial film pattern by processing the sacrificial film into a pattern having desired intervals through etching; coating a third thin film, which is a film different from the sacrificial film, on the sacrificial film pattern; forming sidewall spacers on the sidewalls of the sacrificial film by etching the third thin film; removing the sacrificial film; processing the first thin film and the second thin film by using the sidewall spacers as a mask; coating the processed first thin film and the processed second thin film with a silicon oxide film deposited by intermittently supplying a silicon-containing precursor and an oxygen-containing gas onto the substrate; forming a silicon oxide film pattern by processing the silicon oxide film into a pattern having desired intervals through etching; and introducing impurities into the substrate by using the silicon oxide film pattern as an offset spacer.

According to another aspect of the present invention, there is provided a manufacturing method of a semiconductor device, the manufacturing method including forming a first thin film on a substrate; forming a second thin film, which is a film different from the first thin film, on the first thin film; forming a sacrificial film, which is a film different from the second thin film, on the second thin film; forming a sacrificial film pattern by processing the sacrificial film into a pattern having desired intervals through etching; coating a third thin film, which is a film different from the sacrificial film, on the sacrificial film pattern; forming sidewall spacers on the sidewalls of the sacrificial film by etching the third thin film; removing the sacrificial film; processing the first film and the second film by using the sidewall spacers as a mask; coating the processed first thin film and the second thin film with a silicon oxide film deposited by intermittently supplying a silicon-containing precursor and an oxygen-containing gas onto the substrate; and introducing impurities into the surface of the substrate from above the silicon oxide film by using the silicon oxide film as a protection film according to an ion implantation method.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view showing a manufacturing method of a semiconductor device according to an embodiment of the present invention;

FIG. 2 is a sectional view showing a manufacturing method of a semiconductor device according to an embodiment of the present invention;

FIG. 3 is a sectional view showing a manufacturing method of a semiconductor device according to an embodiment of the present invention;

FIG. 4(A) is a sectional view showing a semiconductor device without an offset spacer, and FIG. 4(B) is a sectional view showing a semiconductor device with an offset spacer;

FIG. 5(A) is a sectional view showing the case where a thin film that becomes an offset spacer is formed by using an LPCVD method, and FIG. 5(B) is a sectional view showing the case where a thin film that becomes an offset spacer is formed by using an MLD method;

FIG. 6 is a sectional view showing the case where a sidewall film is formed of SiN;

FIG. 7 is a sectional view showing the case where a sidewall film is formed of MLD-SiO₂;

FIG. 8 is a sectional view showing the case where an ion implantation protection film is formed;

FIG. 9 is a sectional view showing the case where an ion implantation protection film is formed;

FIG. 10 is a sectional view showing the case where an ion implantation protection film is formed;

FIG. 11 is a sectional view showing the case where an ion implantation protection film is formed;

FIG. 12 is a longitudinal sectional view of a film forming device according to an embodiment of the present invention;

FIG. 13 is a cross-sectional view of the film forming device shown in FIG. 12;

FIG. 14 is a timing chart showing an example of timings to supply gas; and

FIG. 15 a timing chart showing another example of timings to supply gas.

### DETAILED DESCRIPTION OF THE INVENTION

Hereinafter, the present invention will be described in detail by explaining exemplary embodiments of the invention with reference to the attached drawings.

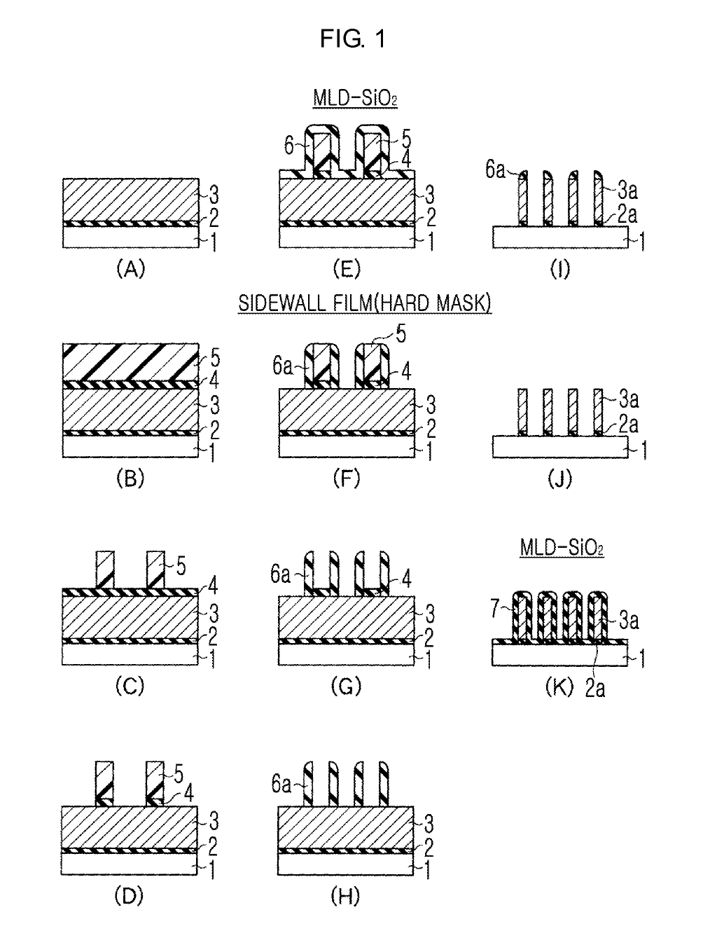

FIGS. 1(A) through 1(K) are sectional views showing a manufacturing method of a semiconductor device according to an embodiment of the present invention.

First, as shown in FIG. 1(A), a high-permittivity insulation film (a high-k film) 2 is formed on a semiconductor substrate, e.g., a silicon substrate 1. The high-k film 2 is a film that becomes a gate insulation film of a transistor. Examples of a material used to form the high-k film 2 may include HfO₂, Al₂O₃, HfSiO, and the like, for example. In the present embodiment, HfO₂ is used to form the high-k film 2. Next, a metal film 3 is formed on the high-k film 2. The metal film 3 is a film that becomes a gate electrode of the transistor. Examples of a material used to form the metal film 3 may include W, TiN, and the like, for example. In the present embodiment, TiN is used to form the metal film 3.

Furthermore, although the metal film 3 is formed as a single metal layer in the present embodiment, the metal film 3 may also be a stacked layer of conductive silicon, e.g., a conductive poly-silicon, and a metal or a stacked layer of different metals.

Next, as shown in FIG. 1(B), an anti-reflection film (BARC) 4 is formed on the metal film 3. Examples of a material used to form the BARC 4 may include an organic film and an inorganic film. In the present embodiment, an organic film is used to form the BARC 4. Next, a sacrificial film 5 is formed on the BARC 4. Examples of a material used to form the sacrificial film 5 may include resin. In the present embodiment, photoresist is used to form the sacrificial film 5. A sacrificial film 5 formed of photoresist may be formed at a low temperature, e.g., 30° C. Therefore, the formation of the sacrificial film 5 at such a low temperature neither oxidizes the high-k film 2 or the metal film 3 nor forms an interface layer, the film quality of the high-k film 2 or the metal film 3 is not deteriorated. Although a silicon nitride film, for example, may be used as the sacrificial film 5, a high temperature is necessary to form the silicon nitride film. For example, the temperature is in a range from 400° to 800° C. As described above, resin that can be formed at a temperature lower than the temperature for forming a silicon nitride film, e.g., photoresist, may be used to form the sacrificial film 5.

Next, as shown in FIG. 1(C), the sacrificial film 5, which is formed of photoresist, is patterned to have a predetermined pattern by using a photolithography method.

Next, as shown in FIG. 1(D), the BARC 4 is etched by using the patterned sacrificial film 5 as a mask (BARC etching).

Next, as shown in FIG. 1(E), a MLD silicon oxide film (MLD-SiO₂) 6 is formed on the patterned sacrificial film 5 and the metal film 3 by using an MLD method. The MLD-SiO₂ 6 is a film that becomes a mask when the metal film 5 is patterned to the shape of a gate electrode (hard mask).

Here, the MLD method is one of thin film growing methods, and is a method of epitaxially growing a thin film to an atomic layer level or a molecular layer level by intermittently supplying a film-forming gas into a processing container. A method for epitaxially growing a thin film to a molecular layer level is referred to as the MLD (Molecular Layer Deposition) method, whereas a method for epitaxially growing a thin film to an atomic layer level is referred to as ALD (Atomic Layer Deposition) method. Although the present embodiment shows an example of using the MLD method, it is also possible to apply the ALD method. However, due to a difference between film-forming rates, the throughput may be lowered in case of using the ALD method.

A thin film may be formed at a low temperature, e.g., a temperature in a range from the room temperature to about 300° C., by using the MLD method. Therefore, a thin film may be conformally formed on the sacrificial film 5 and the metal film 3 without damaging or deforming the sacrificial film 5, which is formed of photoresist.

Furthermore, since a thin film is formed at a low temperature in the MLD method, deterioration of the film quality of the high-k film 2 or the metal film 3 may be suppressed during film formation.

Furthermore, although a silicon oxide film may be formed by using an LPCVD method, low-temperature film formation is originally difficult by using the LPCVD method, and the film forming rate of the LPCVD method is significantly slower than that of the MLD method. Furthermore, a film may be formed at a low temperature by using spin-on-glass (SOG) method. However, if, for example, an applied underlayer includes a step as shown in FIG. 1(D), a thin film cannot be conformally formed along the step.

Therefore, the MLD-SiO₂ 6 may be formed on the patterned sacrificial film 5 and the metal film 3 by using the MLD method, as in the present embodiment.

Furthermore, although a silicon nitride film (SiN) instead of SiO₂ may be used as a film becoming a hard mask, such as the MLD-SiO₂ 6, SiN exhibits a greater film stress than SiO₂, and, if a stacked film of poly-silicon and a metal is used as the metal film 3, it is difficult for SiN to have etching selectivity. Therefore, SiO₂ may be used as the film becoming a hard mask, such as the MLD-SiO₂ 6.

Next, as shown in FIG. 1(F), the MLD-SiO₂ 6 is etched by anisotropical etching, for example, by using RIE method, so that the MLD-SiO₂ 6 remains on sidewalls of the sacrificial film 5 and the BARC 4 and a sidewall film 6a is formed.

Next, as shown in FIG. 1(G), the sacrificial film 5 is removed by etching the sacrificial film 5 by using the sidewall film 6a and the metal film 3 as masks. In the case where the sacrificial film 5 is formed of resin, for example, photoresist, wet etching may be performed to remove the sacrificial film 5. Furthermore, a washing solution, which is used for washing, may be used for the wet-etching, for example. Examples of the washing solution may include a washing solution containing sulfuric acid and oxygenated water.

Next, as shown in FIG. 1(H), the BARC 4 is removed by etching the BARC 4 by using the sidewall film 6a and the metal film 3 as masks. The BARC 4 may also be removed by performing the wet etching described above with reference to FIG. 1(G), e.g., wet etching using a washing solution containing sulfuric acid and oxygenated water.

Next, as shown in FIG. 1(I), the metal film 3 and the high-k film 2 are etched by using the sidewall film 6a as a mask. As a result, the metal film 3 is processed into the shape of gate electrodes 3a, whereas the high-k film 2 is processed into the shape of a gate insulation film 2a.

Next, as shown in FIG. 1(J), if the sidewall film 6a remains on the top surfaces of the gate electrodes 3a, the remaining sidewall film 6a is removed.

Through the operations described above, a process for manufacturing a gate by using the metal film 3 and the high-k film 2 is completed. Hereinafter, a process for forming source/drain regions will begin.

First, as shown in FIG. 1(K), a MLD silicon oxide film (MLD-SiO₂) 7 is formed on the substrate 1, the gate electrodes 3a, and the gate insulation film 2a by using the MLD method. The MLD-SiO₂ 7 is a film that becomes an offset spacer. The film that becomes an offset spacer covers the gate electrodes 3a (metal film) and the gate insulation film 2a (high-k film). Such a film may be formed by using the MLD method in which a thin film is formed at a low temperature. By forming the MLD-SiO₂ 7 on the substrate 1, the gate electrodes 3a, and the gate insulation film 2a by using the MLD method, deterioration of the film qualities of the gate electrodes 3a and the gate insulation film 2a during film formation may be suppressed.

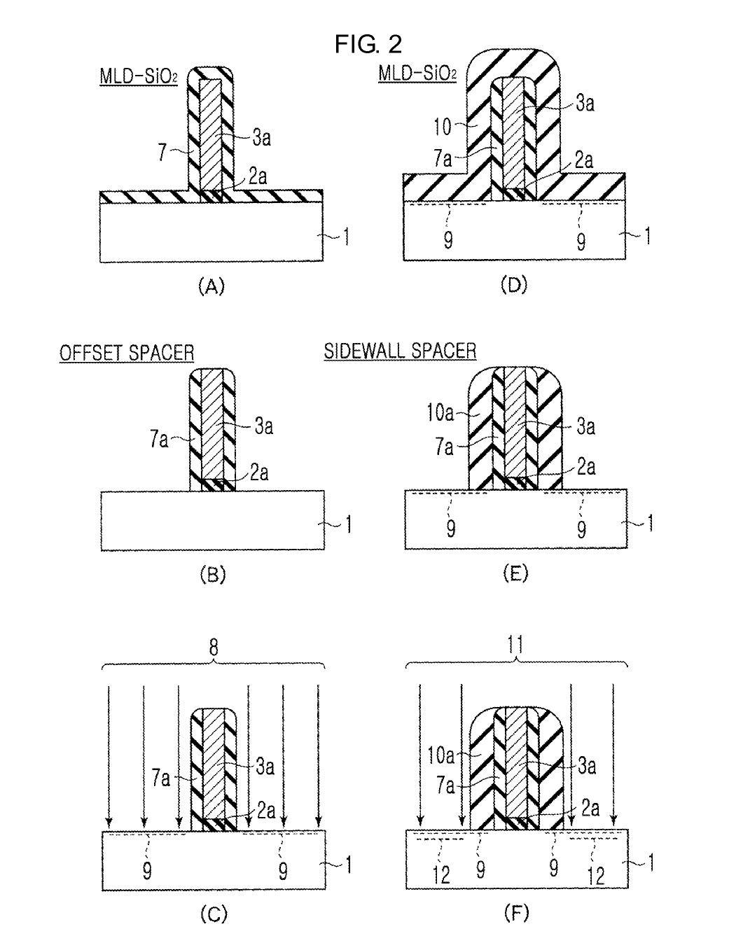

Hereinafter, the manufacturing method of a semiconductor device according to an embodiment of the present invention will be continuously described with reference to FIGS. 2(A) through 2(F), which magnifies and shows one of the gate electrodes 3a.

FIG. 2(A) is a sectional view of one magnified gate electrode 3a from among the gate electrodes 3a shown in FIG. 1(K). As shown in FIG. 2(A), the MLD-SiO₂ 7 is formed on the substrate 1, the gate electrode 3a, and the gate insulation film 2a. Then, as shown in FIG. 2(B), the MLD-SiO₂ 7 is etched by anisotropical etching, for example, by using an RIE method, so that the MLD-SiO₂ 7 remains on sidewalls of the gate electrode 3a and an offset spacer 7a is formed. The offset spacer 7a is a film that functions as described below.

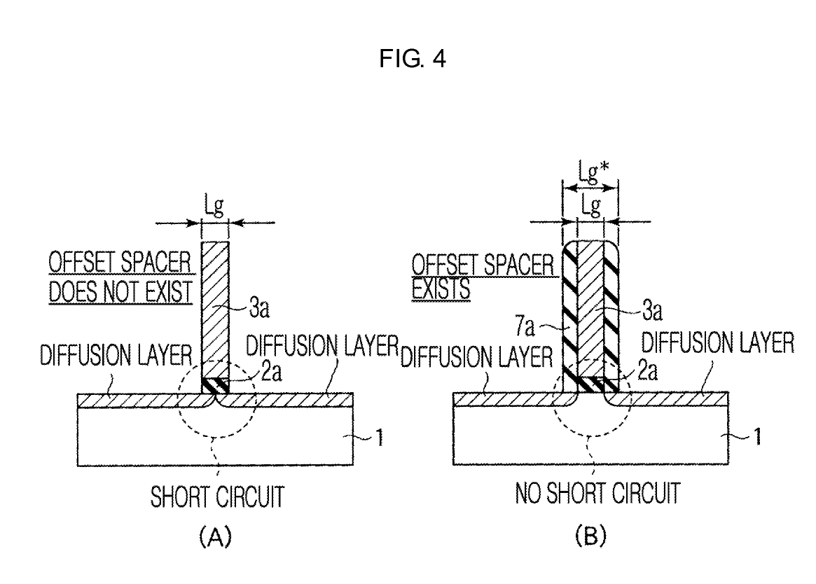

The source/drain regions are formed by introducing either n-type or p-type impurities (arsenic, phosphorus, boron, or the like) into the substrate 1 by using the gate electrode 3a as a mask and diffusing the impurities. At this time, as shown in FIG. 4(A), if a gate length Lg is insufficient, short circuit occurs between diffusion layers (source/drain regions) of the impurities under the gate electrode 3a. Especially, as in the present embodiment, a gate length may be less than or equal to the resolution limit of lithography in the gate electrode 3a, which is manufactured by using the sidewall film 6a as a mask. Therefore, short circuit may easily occur between the diffusion layers.

Therefore, as shown in FIG. 4(B), a gate length Lg* in appearance at the time of impurity introduction is long due to the formation of the offset spacer 7a on the sidewalls of the gate electrode 3a. As a result, short circuit between the diffusion layers may be suppressed even if a gate length is decreased, for example, if the gate length is less than or equal to the resolution limit of lithography.

Next, as shown in FIG. 2(C), either n-type or p-type impurities 8 are introduced into the substrate 1 through ion implantation, for example, by using the gate electrode 3a, on the sidewalls of which the offset spacers 7a are formed. Thus, an introduced region 9, to which the impurities 8 are introduced, is formed in the substrate 1.

Next, as shown in FIG. 2(D), a MLD-SiO₂ 10 is formed on the offset spacers 7a, the gate electrode 3a, and the substrate 1 by using the MLD method. The MLD-SiO₂ 10 is a film that becomes a sidewall spacer. The film that becomes a sidewall spacer covers the gate electrode 3a (metal film) and the gate insulation film 2a (high-k film). Such a film may be formed by using the MLD method in which a thin film is formed at a low temperature. By forming the MLD-SiO₂ 10 on the substrate 1, the gate electrodes 3a, and the gate insulation film 2a by using the MLD method, deterioration of the film qualities of the gate electrodes 3a and the gate insulation film 2a during film formation may be suppressed.

Next, as shown in FIG. 2(E), the MLD-SiO₂ 10 is etched by anisotropical etching, for example, by using an RIE method, so that the MLD-SiO₂ 10 remains on sidewalls of the gate electrode 3a via the offset spacer 7a in the present embodiment, and a sidewall spacer 10a is formed.

Next, as shown in FIG. 2(F), either n-type or p-type impurities 11 are introduced into the substrate 1 through ion implantation, for example, by using the gate electrode 3a, on the sidewall of which the sidewall spacer 10a is formed, as a mask. Thus, an introduced region 12, to which the impurities 11 are introduced, is formed in the substrate 1.

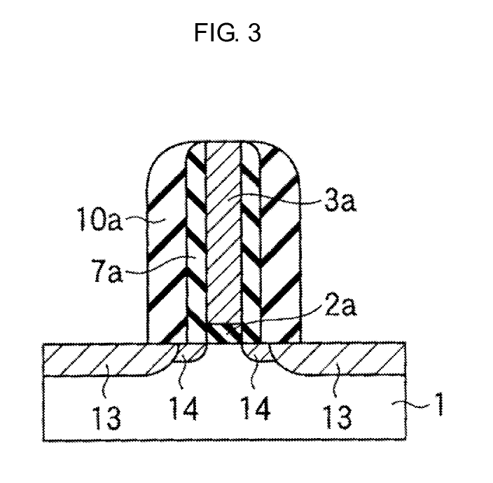

Next, as shown in FIG. 3, the substrate 1 is thermally treated and the impurities introduced into the introduction regions 9 and 12 are diffused in the substrate 1, so that source/drain regions 13 having a conductive type opposite to that of the substrate 1 and source/drain extension regions 14 having an impurity concentration lower than that of the source/drain regions 13 are formed.

According to the manufacturing method as described above, a transistor, that is, an insulation gate type field effect transistor in the present embodiment, in which a metal film having a specific resistance smaller than that of a conductive poly-silicon, for example, is used and a high-k film having a relative permittivity greater than that of SiO₂ for example, is used as the gate insulation film 2a, is manufactured.

According to the manufacturing method according to the above embodiment, as shown in FIG. 1(E), a thin film 6 that becomes the sidewall film (hard mask) 6a is formed by using the MLD method. Therefore, the thin film 6 may be formed at a low temperature, and thus, even if a metal film is used as the gate electrode 3a and a high-k film is used as the gate insulation film 2a, deterioration of the film quality of the metal film or the high-k film during the film formation may be suppressed.

Furthermore, since a thin film that becomes the sidewall film 6a may be formed at a low temperature, the sacrificial film 5 may be formed of resin, e.g., photoresist. By using photoresist to form the sacrificial film 5, the sacrificial film 5 may be formed at low cost compared with the case of forming the sacrificial film 5 of a silicon nitride film or the like, and, since the photoresist itself becomes the sacrificial film 5, a process for etching the sacrificial film 5 by using the photoresist as a mask may be omitted.

Furthermore, according to the manufacturing method according to the above embodiment, as shown in FIGS. 1(K) and 2(A), the thin film 7 that becomes the offset spacer 7a is formed by using the MLD method. Therefore, as described above, deterioration of the film quality of the metal film of the gate electrode 3a or the high-k film of the gate insulation film 2a during the film formation may be suppressed.

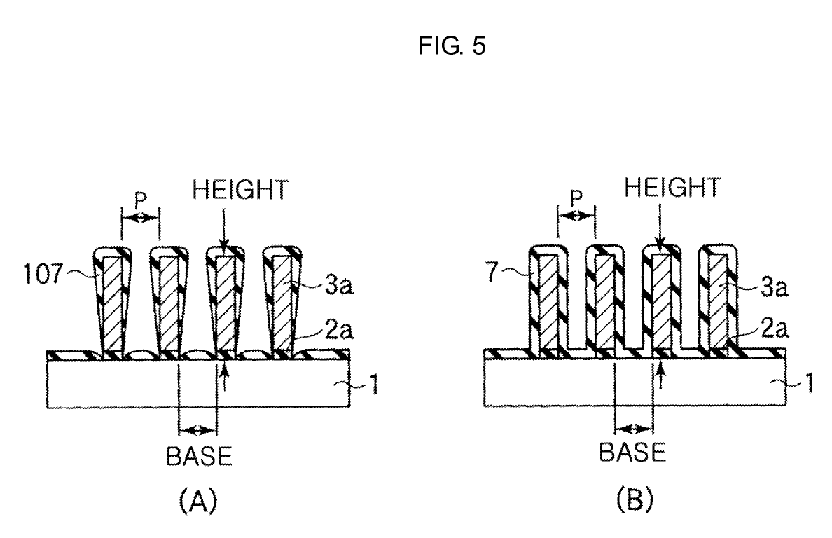

Furthermore, in the case where a pitch p between gates is small, e.g., the pitch p is smaller than or equal to the resolution limit of lithography, if a thin film 107 that becomes an offset spacer is formed by using the LPCVD method, it is difficult to conformally form the thin film 107, as shown in FIG. 5(A).

Furthermore, if the pitch p decreases, an aspect ratio (height/base) may easily increase. If the aspect ratio is high, it is also difficult to conformally form the thin film 107, as in the case in which the pitch p is small.

Meanwhile, according to the manufacturing method according to the above embodiment, the thin film 7 that becomes the offset spacer 7a is formed by using the MLD method. Therefore, as shown in FIG. 5(B), even if the pitch p is small, e.g., the pitch p is smaller than or equal to the resolution limit of lithography (for example, less than or equal to 40 nm), the thin film 7 may be formed more conformally, compared with the case of forming the thin film 7 by using the LPCVD method.

Furthermore, if the aspect ratio is high, e.g., the aspect ratio is 3 or higher, the thin film 7 may be formed more conformally, compared with the case of forming the thin film 7 by using the LPCVD method.

Furthermore, according to the manufacturing method according to the above embodiment, the sidewall film 6a and the offset spacer 7a are formed of a same material, e.g., MLD-SiO₂.

It is assumed below that a sidewall film and an offset spacer are formed of different materials.

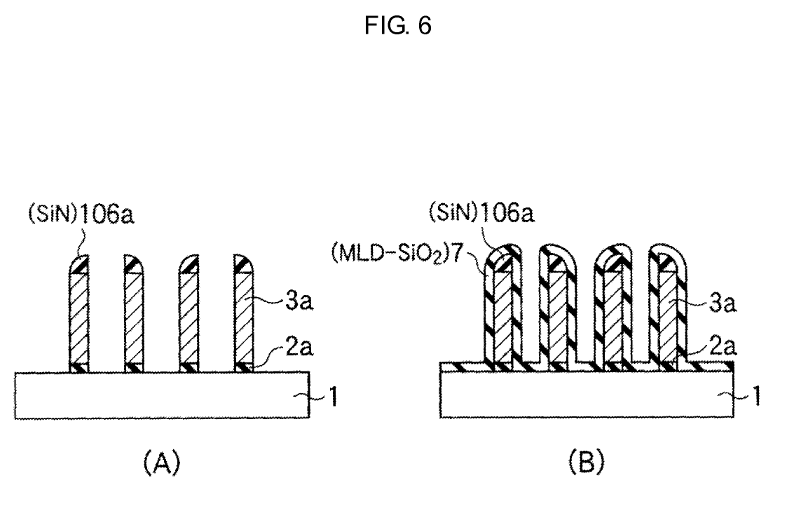

For example, a sidewall film 106a is formed of a silicon nitride film (SiN) as shown in FIG. 6(A), whereas the thin film 7 that becomes an offset spacer is formed of MLD-SiO₂ as shown in FIG. 6(B). In this case, the sidewall film (SiN) 106a remains on the gate electrode 3a due to unstable manufacturing process or the like. SiN has a relative permittivity higher than MLD-SiO₂. Therefore, the relative permittivity of an insulation material around the gate electrode 3a increases. Increase of the relative permittivity due to unstable manufacturing process or the like causes increase of characteristics unevenness between integrated circuits.

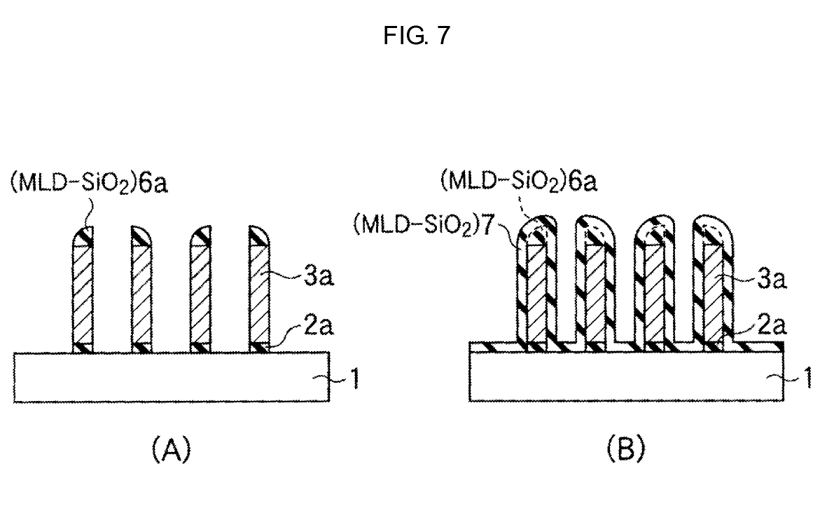

Meanwhile, the sidewall film 6a and the offset spacer 7a are formed of a same material as in the above embodiment. For example, the sidewall film 6a is formed of MLD-SiO₂ as shown in FIG. 7(A), and the thin film 7 that becomes an offset spacer is also firmed of MLD-SiO₂ as shown in FIG. 7(B). As a result, even if the sidewall film 6a remains on the gate electrode 3a due to unstable manufacturing process or the like, increase of the relative permittivity of an insulation material around the gate electrode 3a may be reduced, because the sidewall film 6a and the offset spacer 7a are formed of the same material.

As described above, by forming the sidewall film 6a and the offset spacer 7a using the same material, even in case of process instability or the like, increase of the relative permittivity of an insulation film around the gate electrode 3a may be reduced. Thus, a manufacturing method of a semiconductor device which is highly resistant to process instabilities, and the semiconductor device may be acquired. The same thing may be applied to the sidewall spacer 10a. In other words, the offset spacer 7a and the sidewall spacer 10a are formed of a same material. In the present embodiment, both the offset spacer 7a and the sidewall spacer 10a are formed of MLD-SiO₂. Therefore, a manufacturing method of a semiconductor device including the offset spacer 7a and the sidewall spacer 10a that are highly resistant to process instabilities, and the semiconductor device may be acquired.

Furthermore, in the manufacturing method of a semiconductor device according to the above embodiment, deterioration of film qualities of a metal film and a high-k film are prevented by forming the sidewall film 6a, the offset spacer 7a, and the sidewall spacer 10a by using the MLD method.

However, the present invention is not limitedly applied to the sidewall film 6a, the offset spacer 7a, and the sidewall spacer 10a, but may also be applied to an ion implantation protection film, for example.

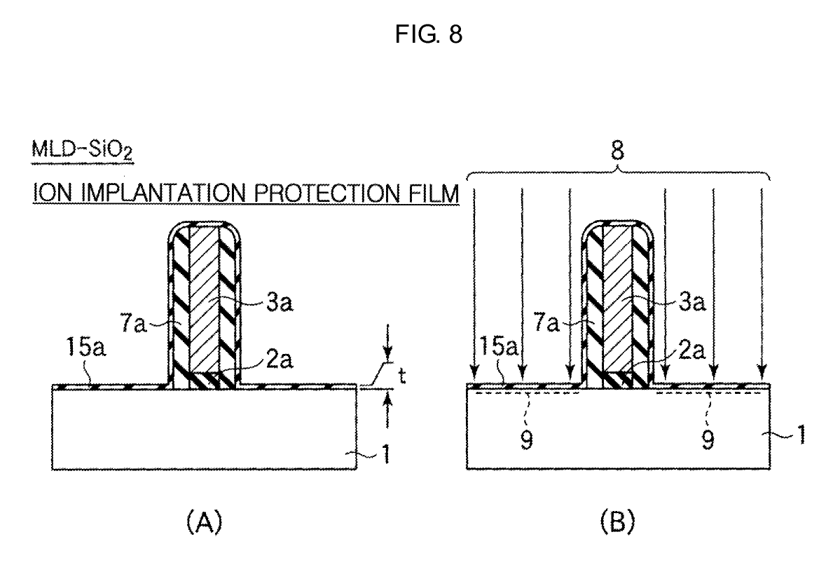

For example, after the offset spacer 7a is formed, an ion implantation protection film 15a is formed on the substrate 1, the offset spacer 7a, and the gate electrode 3a, as shown in FIG. 8(A). The ion implantation protection film 15a is a thin film on the substrate 1, having a thickness t, for example, in a range from about 2 nm to about 10 nm. Next, as shown in FIG. 8(B), either n-type or p-type impurities 8 are ion implanted into the substrate 1 via the ion implantation protection film 15a.

The ion implantation protection film 15a is formed by using the MLD method and is thus formed of MLD-SiO₂, for example.

Generally, an ion implantation protection film is acquired by thermally oxidizing the substrate 1, for example. However, in the case where a metal film is used as the gate electrode 3a and a high-k film is used as the gate insulation film 2a, if an ion implantation protection film tries to be acquired via thermal oxidization, the film qualities of the gate electrode 3a and the gate insulation film 2a may be deteriorated due to heat used during the thermal oxidization.

Meanwhile, if the ion implantation protection film 15a is formed by using the MLD method as in the present embodiment, the ion implantation protection film 15a may be formed at a temperature in a range from about the room temperature to about 300° C., and thus deterioration of the film qualities of the gate electrode 3a and the gate insulation film 2a may be suppressed.

Furthermore, an ion implantation protection film may also be acquired by reducing the thickness t of the thin film 7 on the substrate 1, which becomes the offset spacer 7a, to a thickness in a range from 2 nm to 10 nm, for example.

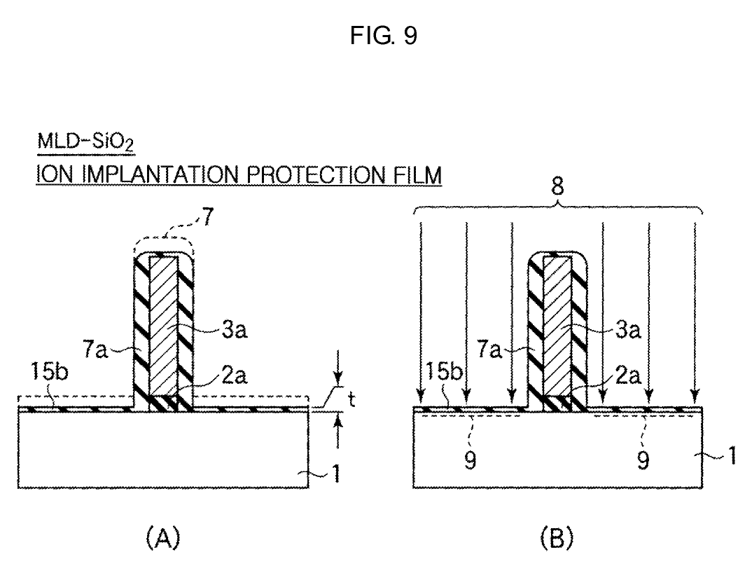

For example, as shown in FIG. 9(A), the thin film 7, which is formed by using the MLD method and becomes an offset spacer formed of, for example, MLD-SiO₂, is etched so that the thickness t of the thin film 7 on the substrate 1 is in a range from about 2 nm to about 10 nm, for example. As a result, both the offset spacer 7a and the ion implantation protection film 15b may be acquired from the thin film 7. Next, as shown in FIG. 9(B), either n-type or p-type impurities are ion implanted into the substrate 1 via the ion implantation protection film 15b.

Furthermore, an ion implantation protection film may also be used for impurity introduction performed after formation of the sidewall spacer 10a.

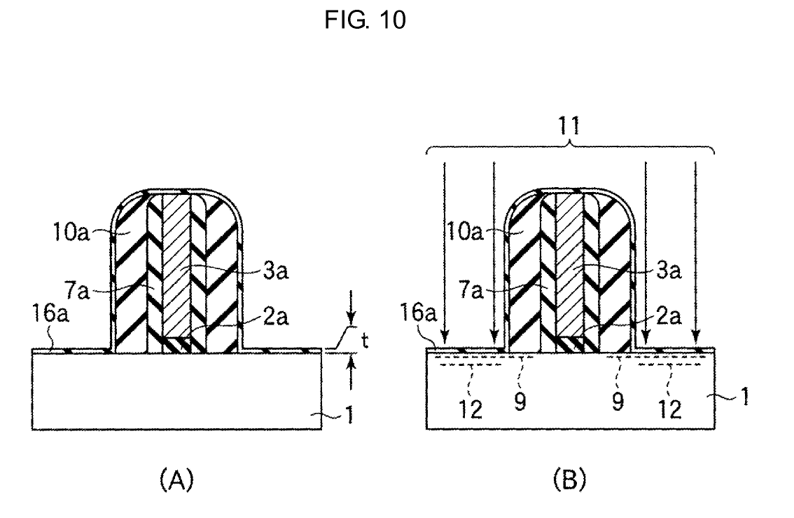

For example, as shown in FIG. 10(A), after the sidewall spacer 10a is formed, an ion implantation protection film 16a is formed on the substrate 1, the sidewall spacer 10a, the offset spacer 7a, and the gate electrode 3a. The ion implantation protection film 16a is a thin film on the substrate 1, having a thickness in a range from about 2 nm to about 10 nm, for example. Next, as shown in FIG. 10(B), either n-type or p-type impurities are ion implanted into the substrate 1 via the ion implantation protection film 16a.

It is obvious that the ion implantation protection film used for ion introduction performed after formation of the sidewall spacer 10a may be formed together with the sidewall spacer 10a.

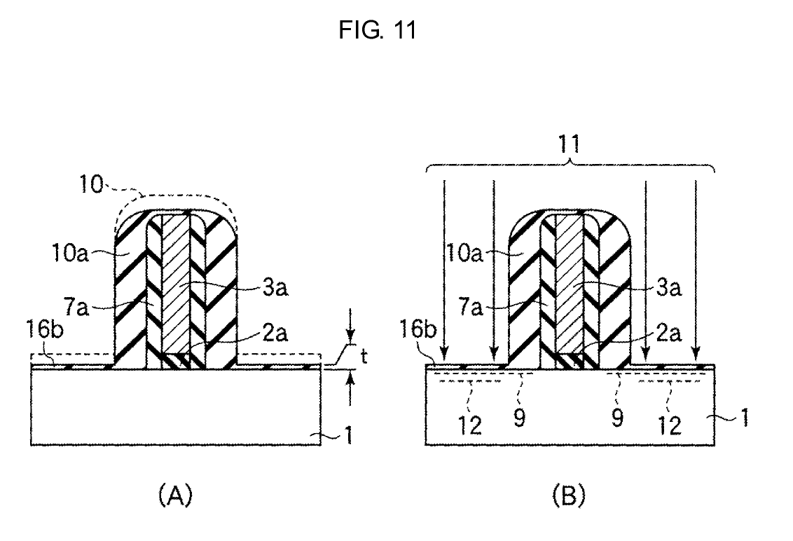

For example, as shown in FIG. 11(A), a thin film 10, which is formed by using the MLD method and becomes a sidewall spacer formed of, for example, MLD-SiO₂, is etched so that the thickness t of the thin film 10 on the substrate 1 is in a range from 2 nm to 10 nm, for example. As a result, both the sidewall spacer 10a and an ion implantation protection film 16b may be acquired from the thin film 10. Next, as shown in FIG. 11(B), either n-type or p-type impurities are ion implanted into the substrate 1 via the ion implantation protection film 16b.

As described above, in case of using an ion implantation protection film, deterioration of the film qualities of the gate electrode 3a and the gate insulation film 2a may be suppressed due to the formation of the ion implantation protection film by using the MLD method.

Next, an example of a film forming device used in a manufacturing method of a semiconductor device according to embodiments of the present invention will be described.

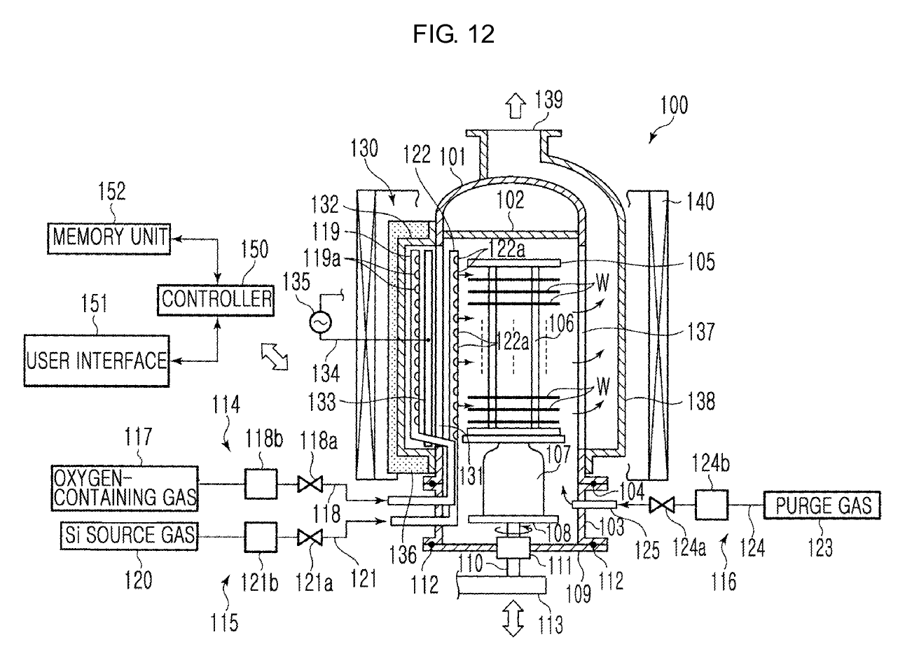

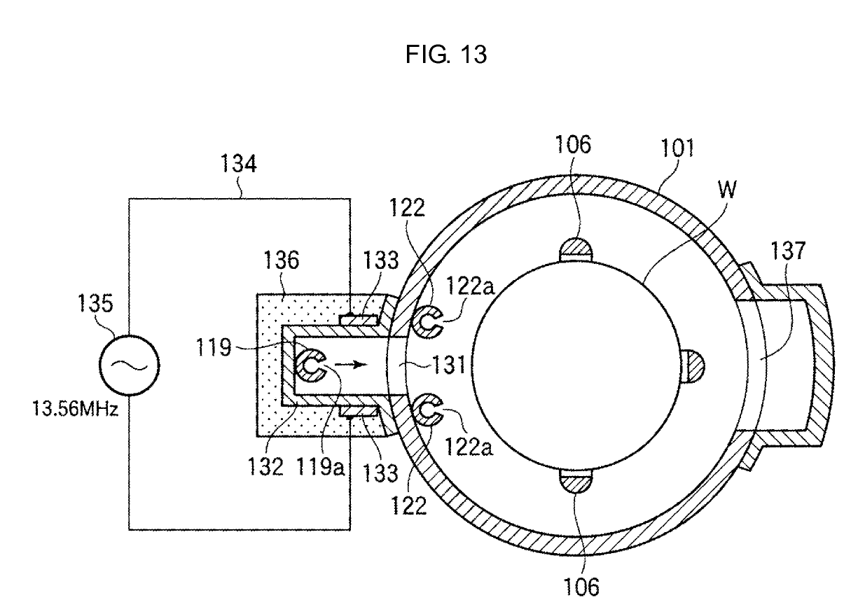

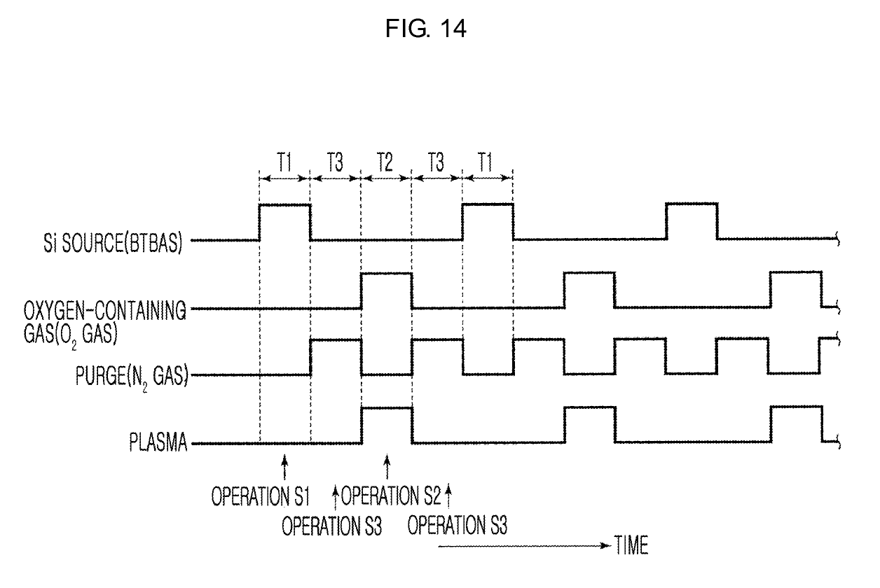

FIG. 12 is a longitudinal-sectional view of a film forming device according to an embodiment of the present invention, FIG. 13 is a cross-sectional view of the film forming device shown in FIG. 12, and FIG. 14 is a timing chart showing supply gas timing. Furthermore, a heating device is omitted in FIG. 13.

A film forming device 100 includes a processing container 101 having a shape of a bottom-open cylinder with the ceiling. The entire processing container 101 is formed of quartz, for example, and a quartz ceiling plate 102 is formed on the ceiling of the processing container 101 to seal the processing container 101. Furthermore, a manifold 103, which is formed of a stainless steel, for example, and have a cylindrical shape, is connected to a bottom opening of the processing container 101 via a sealing member 104, such as an O-ring.

The manifold 103 supports the bottom of the processing container 101, and a quartz wafer boat 105, on which a plurality of, for example, e.g., 50 to 100, semiconductor wafers (semiconductor substrates) W as objects to be processed can be held in multiple layers, may be inserted from below the manifold 103 into the processing container 101. The wafer boat 105 has three pillars 106 (refer to FIG. 13), so that a plurality of wafers W are supported by grooves formed on the pillars 106.

The wafer boat 105 is disposed on a table 108 via a quartz thermos vessel 107, and the table 108 is supported by a rotation shaft 110, which penetrates a stainless steel cover unit 109 for opening and closing the bottom opening of the manifold 103.

Furthermore, a magnetic fluid seal 111, for example, is formed on a portion of the rotation shaft 110 penetrating the cover unit 109 so as to tightly seal the rotation shaft 110 and to rotatably support the rotation shaft 110. Furthermore, a sealing member 112, e.g., an O-ring, is installed between the peripheral portion of the cover unit 109 and the bottom of the manifold 103 to hold sealing of the processing container 101.

The rotation shaft 110 is attached to the front end of an arm 113 supported by an elevating mechanism (not shown), such as a boat elevator, and is configured so that the wafer boat 105 and the cover unit 109 are elevated together and are inserted to and pulled out from the processing container 101. Furthermore, the table 108 may also be fixedly installed on the cover unit 109's side, so that wafers W are processed without rotating the wafer boat 105.

Furthermore, the film forming device 100 includes an oxygen-containing gas supply mechanism 114 for supplying an oxygen-containing gas into the processing container 101, a Si source gas supply mechanism 115 for supplying a Si source gas into the processing container 101, and a purge gas supply mechanism 116 for supplying an inert gas into the processing container 101 to serve as a purge gas. Examples of the oxygen-containing gas include O₂ gas, examples of the Si source gas include BTBAS (bis(tertiarybutylamino)silane), and examples of the inert gas include N₂ gas.

The oxygen-containing gas supply mechanism 114 includes an oxygen-containing gas supply source 117, an oxygen-containing gas piping 118 which guides the oxygen-containing gas from the oxygen-containing gas supply source 117, and an oxygen-containing gas spreading nozzle 119, wherein the oxygen-containing gas spreading nozzle 119 is a quartz pipe which is connected to the oxygen-containing gas piping 118, penetrates a sidewall of the manifold 103 inwardly, is bent upward, and vertically extends. A plurality of gas ejecting holes 119a are formed apart from each other at intervals of a predetermined distance in the vertically extending portion of the oxygen-containing gas spreading nozzle 119, so that the oxygen-containing gas, e.g., O₂ gas, may be ejected from each of the gas ejecting holes 119a almost uniformly in a horizontal direction toward the processing container 101.

Furthermore, the Si source gas supply mechanism 115 includes an Si source gas supply source 120, an Si source gas piping 121 which guides an Si source gas from the Si source gas supply source 120, and an Si source gas spreading nozzle 122, wherein the Si source gas spreading nozzle 122 is a quartz pipe which is connected to the Si source gas piping 121, penetrates a sidewall of the manifold 103 inwardly, is bent upward, and vertically extends. Here, two Si source gas spreading nozzles 122 are formed (refer to FIG. 13), and a plurality of gas ejecting holes 122a are formed apart from each other at intervals of a predetermined distance in the vertically extending portion of each of the Si source gas spreading nozzles 122, so that the Si source gas may be ejected from each of the gas ejecting holes 122a almost uniformly in a horizontal direction toward the processing container 101. Furthermore, only one Si source gas spreading nozzle 122 may be formed.

Furthermore, the purge gas supply mechanism 116 includes an purge gas supply source 123, a purge gas piping 124 which guides a purge gas from the purge gas supply source 123, and a purge gas spreading nozzle 125, wherein the purge gas spreading nozzle 125 is connected to the purge gas piping 124 and penetrates a sidewall of the manifold 103.

Opening valves 118a, 121a, and 124a and flow controllers 118b, 121b, and 124b, such as mass-flow controllers, are respectively formed on the oxygen-containing gas piping 119, the Si source gas piping 121, and the purge gas piping 124, so that flow of each of oxygen containing gas, Si source gas, and purge gas to may be controlled and supplied.

A plasma generating mechanism 130 for generating plasma of oxygen containing gas is formed on a portion of the sidewall of the processing container 101. The plasma generating mechanism 130 includes a plasma partitioning wall 132, where the plasma partitioning wall 132 is tightly welded to the outer wall of the processing container 101 to cover a long and narrow opening 131, which is formed by vertically cutting the sidewall of the processing container 101 by a predetermined width. The plasma partitioning wall 132 has a recessed sectional shape, is formed to be vertically long and narrow, and is formed of quartz, for example. Furthermore, the plasma generating mechanism 130 includes a pair of long and narrow plasma electrodes 133, which are vertically arranged on outer surfaces of two sidewalls of the plasma partitioning wall 132 so as to face each other, and a high frequency power supply source 135, which is connected to the plasma electrodes 133 via a power feeding line 134 and supplies high frequency power to the plasma electrodes 133. Furthermore, plasma of an oxygen containing gas may be generated by applying a high frequency power of 13.56 MHz, for example, from the high frequency power supply source 135 to the plasma electrodes 133. Furthermore, the frequency of the high frequency voltage is not limited to 13.56 MHz, and the high frequency voltage may have the other frequency, e.g., 400 kHz.

By forming the plasma partitioning wall 132 as described above, a portion of the sidewall of the processing container 101 becomes recessed outward as seen from the inside, and thus the space inside the plasma partitioning wall 132 communicates with the space inside the processing container 101. Furthermore, the opening 131 has a vertical length sufficient to cover all of the wafers W held by the wafer boat 105 in the height-wise direction.

The oxygen containing gas spreading nozzle 119 extends upward in the processing container 101 and is bent toward the outside of the processing container 101 in the radial direction of the processing container 101, so that the oxygen containing gas spreading nozzle 119 stands vertically upward along the innermost portion of the plasma partitioning wall 132 (the portion farthest from the center of the processing container 101). Therefore, when the high frequency power supply source 135 is turned on and a high frequency electric field is formed between the two electrodes 133, oxygen gas ejected from the gas ejecting holes 119a of the oxygen containing gas spreading nozzle 119 is plasmarized and is diffused and flows toward the center of the processing container 101.

An insulation protection cover 136 formed of, for example, quartz, is attached to the plasma partitioning wall 132 from outside so as to cover the plasma partitioning wall 132. Furthermore, a coolant path (not shown) is formed on an inside portion of the insulation protection cover 136, so that the plasma electrodes 133 may be cooled by flowing cooled nitrogen gas, for example, through the coolant path.

The two Si source gas spreading nozzles 122 are formed to vertically stand at locations on the inner wall of the processing container 101 around the opening 131, so that Si source gas may be ejected toward the center of the processing container 101 from the plurality of gas ejecting holes 122a formed on the Si source gas spreading nozzles 122.

Meanwhile, an exhaustion hole 137 for vacuum exhausting the interior of the processing container 101 is formed on a portion of the processing container 101, the portion opposite to the opening 131. The exhaustion hole 137 is formed to be long and narrow by vertically cutting the sidewall of the processing container 101. An exhaustion hole cover unit 138 having the U-shaped cross-section to cover the exhaustion hole 137 is weld-attached to a portion of the processing container 101 corresponding to the exhaustion hole 137. The exhaustion hole covering unit 138 extends upward along the sidewall of the processing container 101, so that a gas outlet 139 is defined on the top of the processing container 101. Furthermore, gas in the processing container 101 is vacuum-sucked from the gas outlet 139 by a vacuum exhaustion mechanism (not shown), which includes a vacuum pump or the like. Furthermore, a barrel-shaped heating device 140 for heating the processing container 101 and wafers W therein, is formed to surround the outer perimeter of the processing container 101.

A controller 150, which includes, for example, a microprocessor (computer), controls each component of the film forming device 100. For example, the controller 150 supplies/stops each gas by opening/closing the valves 118a, 121a, and 124a, controls flow of gas via the mass-flow controllers 118b, 121a, and 124b, controls turning on and off of the high frequency power supply source 135, and controls the heating unit 140. A user interface 151, such as a keyboard to perform command input and the like so that a process manager may manage the film forming device 100, a display to visually display an operational status of the film forming device 100, or the like, is connected to the controller 150.

Furthermore, a memory unit 152, which contains a control program for accomplishing various processes executed in the film forming device 100 under the control of the controller 150, or a program, that is, a recipe, for instructing each component of the film forming device 100 to execute a process according to process conditions, is connected to the controller 150. The recipe is stored in a recording medium in the memory unit 152. The recording medium may be a hard disk or a semiconductor memory, or may be a portable medium such as a CD-ROM, a DVD, and a flash memory. Alternatively, the recipe may be suitably transmitted from another device, for example, via a dedicated line.

Furthermore, if required, processes desired by the film forming device 100 may be performed under the control of the controller 150 by calling a recipe from the memory unit 152 according to instructions or the like from the user interface 151 and performing the recipe in the controller 150.

Next, a method of forming a SiO₂ film according to the present embodiment, the method performed in the film forming device 100 having a configuration as described above, will be described with reference to FIG. 14.

First, at the room temperature, the wafer boat 105 on which, for example, 50 to 100 wafers W, are stacked is loaded into the processing container 101 set at a predetermined temperature in advance, by being lifted from below the processing container 101, and the bottom opening of the manifold 103 is closed by the cover unit 109 so that the processing container 101 is tightly sealed. The diameter of each of the wafers W shown in FIG. 14 is 300 mm.

Then, the processing container 101 is vacuum-sucked to maintain the internal pressure of the processing container 101 at a predetermined processing pressure. At the same time, power supplied to the heating unit 140 is controlled, the temperature of the wafers W is increased to a processing temperature, the processing temperature is maintained, and a film formation process begins when the wafer boat 105 is rotated.

Here, as shown in FIG. 14, the film formation process includes an operation S1 for absorbing a Si source by flowing a Si source gas, e.g., an aminosilane gas having two amino groups per molecule (BTBAS, for example), an operation S2 for oxidizing the Si source gas by supplying an oxygen radical, which is formed by exiting an oxygen containing gas, into the processing container 101, and an operation S3 for removing gas remaining in the processing container 101 from the processing container 101. The operations S1 and S2 are alternately repeated, and the operation S3 is performed between the operations S1 and S2.

In detail, in the operation S1, an aminosilane gas, e.g., BTBAS, having two amino groups per molecule, is supplied as the Si source gas from the Si source gas supply source 120 of the Si source gas supply mechanism 115 into the processing container 101 via the Si source gas piping 121, the Si source gas spreading nozzles 122, and the gas ejection holes 122a for a period of time T1. As a result, a Si source is absorbed onto semiconductor wafers. For example, the period of time T1 is in a range from 1 second to 180 seconds. Furthermore, for example, the flow of the Si source gas is in a range from 1 mL/min(sccm) to 1000 mL/min(sccm). Furthermore, for example, the internal pressure of the processing container 101 is in a range from 13.3 Pa to 1333 Pa (from 0.1 Torr to 10 Torr).

In this case, examples of the aminosilane gas having the two amino groups per molecule and used as a Si source gas, may include BDEAS (bis(diethylamino) silane) and BDMAS (bis(dimethylamino)silane), in addition to the BTBAS. Since each of the above exemplary gases has a small number of amino groups per molecule, that is, two amino groups per molecule, it is structurally difficult for the gases to become a hindrance (structural hindrance) to absorption reaction of Si as compared with aminosilane gases having three amino groups per molecule. Furthermore, since the aminosilane gases having two amino groups per molecule are more stable than aminosilane gases having one amino group per molecule, the BTBAS from among the aminosilane gases having two amino groups per molecule, is the most preferable.

In the operation S2 for supplying the oxygen radical, an oxygen containing gas, e.g., O₂ gas, from the oxygen containing gas supply source 117 of the oxygen containing gas supply mechanism 114 is ejected from the gas ejecting holes 119a via the oxygen containing gas piping 118 and the oxygen containing gas spreading nozzle 119. At this time, the high frequency power supply source 135 of the plasma generating mechanism 130 is turned on to form a high frequency electric field, so that the oxygen containing gas, e.g., O₂ gas, is plasmarized by using the high frequency electric field. Then, the plasmarized oxygen containing gas is supplied into the processing container 101. As a result, the Si source absorbed onto semiconductor wafers W is oxidized, and thus SiO₂ is formed. For example, a period of time T2 for this operation is in a range from 1 second to 300 seconds. Furthermore, for example, the flow of the oxygen containing gas is in a range from 100 mL/min(sccm) to 20000 mL/min(sccm), although the flow of the oxygen containing gas may vary according to a stacked number of semiconductor wafers W. Furthermore, for example, the frequency of the high frequency power supply source 135 is 13.56 MHz, and the power is in a range of from 5 W to 1000 W. Furthermore, for example, the internal pressure of the processing container 101 is in a range from 13.3 Pa to 1333 Pa (from 0.1 Torr to 10 Torr).

In this case, examples of the oxygen containing gas may include NO gas, N₂O gas, H₂O gas, and O₃ gas, in addition to O₂ gas, and the gases are plasmarized by using a high frequency electric field and are used as an oxidizer. Although the oxidizer is not limited to plasma of oxygen containing gases as long as the oxidizer is an oxygen radical, it is preferable to use the plasma of the oxygen containing gas as an oxidizer. From among plasmas of oxygen containing gases, O₂ plasma is the most preferable. By using an oxygen radical, and more particularly, plasma of an oxygen containing gas, as an oxidizer, a SiO₂ film may be formed at a temperature less than or equal to 300° C., and more preferably, at a temperature less than or equal to 100° C. Ideally, a SiO₂ film may be formed even at the room temperature.

Furthermore, the operation S3, which is performed between the operation S1 and the operation S2, is an operation for removing gas remaining in the processing container 101 after the operation S1 or the operation S2, so that a desired reaction occurs in a next operation. Thus, the operation S3 is performed by vacuum-exhausting the interior of the processing container 101 and at the same time supplying an inert gas, e.g. N₂ gas, as a purge gas from the purge gas supply source 123 of the purge gas supply mechanism 116 via the purge gas piping 124 and the purge gas spreading nozzle 125. For example, a period of time T3 for this operation is in a range from 1 second to 60 seconds. Furthermore, for example, the flow of the purge gas is in a range from 50 mL/min(sccm) to 20000 mL/min(sccm).

Furthermore, in the operation S3, as long as the gas remaining in the processing container 101 can be removed, vacuum-suction may be continuously performed without supplying a purge gas when supplies of all gases are stopped. However, by supplying a purge gas, the gas remaining in the processing container 101 may be removed in a short period of time. Furthermore, for example, the internal pressure of the processing vessel 101 is in a range from 13.3 Pa to 1333 Pa (from 0.1 Torr to 10 Torr).

Accordingly, by repeating alternated and intermittent supplies of a Si source gas and an oxygen containing plasma as an oxygen radical and performing the operation S3, for removing gas from the interior of the processing container 101, therebetween, a thin-film of SiO₂ film may be repeatedly stacked one-by-one until the overall thickness of the stacked SiO₂ films reaches a predetermined thickness.

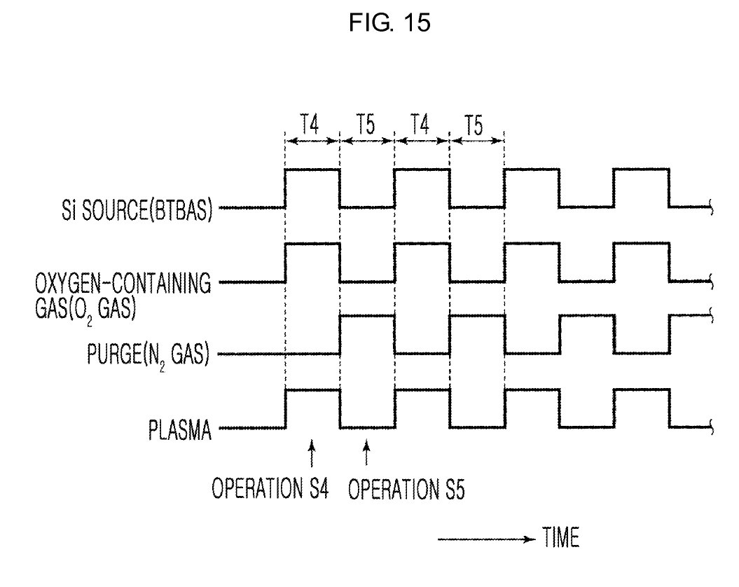

Furthermore, a modified example of the method of forming a SiO₂ film according to the above embodiment will be described with reference to FIG. 15.

Although a Si source gas and an oxygen radical are completely alternately supplied in the above embodiment, an operation S4 for supplying an oxygen radical and an operation S5 for removing gas remaining in the processing container 101 may be alternately and repeatedly performed while the Si source gas is being supplied.

As described above, based on the ALD or MLD method by which a film with a favorable film quality may be formed essentially at a low temperature, an aminosilane gas, which is represented by BTBAS, has two amino groups per molecule, is highly reactive as a Si source, and hardly causes a structural hindrance is used, and an oxygen radical, such as O₂ gas plasma, which is formed when a reaction does not increase a temperature in an oxidization process, is used. Therefore, a SiO₂ film with a favorable film quality may be formed at a temperature less than or equal to 100° C., and further, at a low temperature, such as the room temperature, at a high film-forming rate.

In the above embodiment, although a film may be formed basically at an extremely low temperature, such as a temperature less than or equal to 100° C., a film may also be formed at a temperature higher than the extremely low temperature. However, as a temperature for film formation rises, unevenness of film thickness increases, and the film thickness unevenness may not be negligible if the temperature for film formation exceeds 300° C. Therefore, it is preferable that the temperature for film formation is less than or equal to 300° C. More preferably, a range of a temperature for formation of an ALD or MLD silicon oxide film may be from 180° to 250° C.

As described above, according to the manufacturing method of a semiconductor device according to the above embodiments of the present invention, deterioration of the film quality of a metal film or a high-k film may be suppressed.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A manufacturing method of a semiconductor device, the manufacturing method comprising:
forming a first thin film on a substrate;
forming a second thin film, which is different from the first thin film, on the first thin film;
forming a sacrificial film formed of a film different from the second thin film, on the second thin film;
forming a sacrificial film pattern by processing the sacrificial film into a pattern having desired intervals through etching;
coating a silicon oxide film on the sacrificial film pattern by intermittently supplying a silicon-containing precursor and an oxygen-containing gas onto the substrate;
forming sidewall spacers on the sidewalls of the sacrificial film by etching the silicon oxide film;
removing the sacrificial film; and
processing the first film and the second film by using the sidewall spacers as a mask.

2. The manufacturing method of claim 1, wherein the processed first thin film is a high permittivity dielectric gate, and the processed second thin film is a metal gate electrode.

3. The manufacturing method of claim 1, wherein the coating the silicon oxide film comprises:
forming an absorbing layer by supplying the silicon-containing precursor onto the substrate; and
forming the silicon oxide film by supplying a radical of the oxygen-containing gas onto the substrate and making the radical react with the absorbing layer,
wherein the forming the absorbing layer and the forming the silicon oxide film are repeated a plurality of times until a silicon oxide film with a desired thickness is acquired.

4. The manufacturing method of claim 3, wherein the silicon-containing precursor is BTBAS (bis(tertiarybutylamino)silane).

5. The manufacturing method of claim 3, wherein, in the forming the silicon oxide film, the oxygen-containing gas is a gas selected from the group consisting of oxygen, nitrogen oxide, dinitrogen monooxide, or is a combination of two or more of the gases.

6. The manufacturing method of claim 3, wherein, in the forming the silicon oxide film, the silicon oxide film is formed by supplying an oxygen radical onto the substrate and making the oxygen radical react with the absorbing layer.

7. The manufacturing method of claim 1, wherein the coating the silicon oxide film is performed at a temperature in a range from 180° C. to 250° C.

8. The manufacturing method of claim 1, wherein the coating a silicon oxide film comprises coating stepped portions with an aspect ratio equal to or greater than 3.

9. A manufacturing method of a semiconductor device, the manufacturing method comprising:
forming a first thin film on a substrate;
forming a second thin film, which is different from the first thin film, on the first thin film;
forming a sacrificial film, which is a film different from the second thin film, on the second thin film;
forming a sacrificial film pattern by processing the sacrificial film into a pattern having desired intervals through etching;
coating a third thin film, which is a film different from the sacrificial film, on the sacrificial film pattern;
forming sidewall spacers on the sidewalls of the sacrificial film by etching the third thin film;
removing the sacrificial film;
processing the first thin film and the second thin film by using the sidewall spacers as a mask;
coating the processed first thin film and the processed second thin film with a silicon oxide film deposited by intermittently supplying a silicon-containing precursor and an oxygen-containing gas onto the substrate;
forming a silicon oxide film pattern by processing the silicon oxide film into a pattern having desired intervals through etching; and
introducing impurities into the substrate by using the silicon oxide film pattern as an offset spacer.

10. The manufacturing method of claim 9, wherein the processed first thin film is a high permittivity dielectric gate, the processed second thin film is a metal gate electrode, and the third thin film is a silicon oxide film or a silicon nitride film.

11. The manufacturing method of claim 9, wherein the coating the silicon oxide film comprises:
forming an absorbing layer by supplying the silicon-containing precursor onto the substrate; and
forming an silicon oxide film by supplying radical of an oxygen-containing gas onto the substrate and making the radical react with the absorbing layer,
wherein the forming an absorbing layer and the forming an silicon oxide film are repeated for a plurality of times until a silicon oxide film with a desired thickness is acquired.

12. The manufacturing method of claim 9, wherein the silicon-containing precursor is BTBAS (bis(tertiarybutylamino)silane).

13. The manufacturing method of claim 12, wherein, in the forming a silicon oxide film, the oxygen-containing gas is a gas selected from a group containing oxygen, nitrogen oxide, dinitrogen monooxide, or is a combination of two or more of the gases.

14. The manufacturing method of claim 12, wherein, in the forming a silicon oxide film, a silicon oxide film is formed by supplying an oxygen radical onto the substrate and making the oxygen radical react with the absorbing layer.

15. The manufacturing method of claim 9, wherein the coating a silicon oxide film is performed at a temperature in a range from 180° C. to 250° C.

16. The manufacturing method of claim 9, wherein the coating a silicon oxide film comprises coating stepped portions with an aspect ratio equal to or greater than 3.

17. A manufacturing method of a semiconductor device, the manufacturing method comprising:
forming a first thin film on a substrate;
forming a second thin film, which is a film different from the first thin film, on the first thin film;
forming a sacrificial film, which is a film different from the second thin film, on the second thin film;
forming a sacrificial film pattern by processing the sacrificial film into a pattern having desired intervals through etching;
coating a third thin film, which is a film different from the sacrificial film, on the sacrificial film pattern;
forming sidewall spacers on the sidewalls of the sacrificial film by etching the third thin film;
removing the sacrificial film;
processing the first film and the second film by using the sidewall spacers as a mask;
coating the processed first thin film and the second thin film with a silicon oxide film deposited by intermittently supplying a silicon-containing precursor and an oxygen-containing gas onto the substrate; and
introducing impurities into the surface of the substrate from above the silicon oxide film by using the silicon oxide film as a protection film according to an ion implantation method.

18. The manufacturing method of claim 17, wherein the processed first thin film is a high permittivity dielectric gate, the processed second thin film is a metal gate electrode, and the third thin film is a silicon oxide film or a silicon nitride film.

19. The manufacturing method of claim 17, wherein the coating the silicon oxide film comprises:
forming an absorbing layer by supplying the silicon-containing precursor onto the substrate; and
forming an silicon oxide film by supplying a radical of an oxygen-containing gas onto the substrate and making the radical react with the absorbing layer,
wherein the forming an absorbing layer, and the forming an silicon oxide film are repeated a plurality of times until a silicon oxide film with a silicon film with a desired thickness is acquired.

20. The manufacturing method of claim 19, wherein the silicon-containing precursor is BTBAS (bis(tertiarybutylamino)silane).

21. The manufacturing method of claim 19, wherein, in the forming a silicon oxide film, the oxygen-containing gas is a gas selected from a group consisting of oxygen, nitrogen oxide, dinitrogen monooxide, or is a combination of two or more of the gases.

22. The manufacturing method of claim 19, wherein, in the forming a silicon oxide film, a silicon oxide film is formed by supplying an oxygen radical onto the substrate and making the oxygen radical react with the absorbing layer.

23. The manufacturing method of claim 17, wherein the coating the silicon oxide film is performed at a temperature in a range from 180° C. to 250° C.

24. The manufacturing method of claim 19, wherein the coating a silicon oxide film comprises coating stepped portions with an aspect ratio equal to or greater than 3.
